(19) United States
(12) Patent Application Publication
(10) Pub. No.: US 2005/0069141 A1
(43) Pub. Date: Mar. 31, 2005

(54) Electronic device

(76) Inventor: Jen-Yuan Huang, Sijhih City (TW)

Correspondence Address: RABIN & Berdo, PC, 1101 14TH STREET, NW, SUITE 500, WASHINGTON, DC, 20005, US

(21) Appl. No.: 10/812,079

(22) Filed: Mar. 30, 2004

(30) Foreign Application Priority Data
Sep. 29, 2003 (TW) 92126915

(51) Int. Cl. H03G 11/00; H04R 29/00

(52) U.S. Cl. 381/56; 381/71.3

(57) ABSTRACT

An electronic device connected to at least one fan, which produces some noises and at least one signal during its operation. The electronic device includes a signal detection unit and a control processing unit. The signal detection unit detects the signal produced by the fan. The control processing unit makes a judgement according to the signal and controls playing of music accordingly. The designs of the invention for making the judgement and controlling the playing of music according to the signal produced by the fan may greatly reduce the complaints of users with respect to noises produced by the operating fan, and thus achieve the object of converting noises of the fan into music.

This application claims the benefit of Taiwan application Serial No. 92126915, filed Sep. 29, 2003.

### BACKGROUND OF THE INVENTION

1. Field of the Invention

The invention relates to an electronic device, and more particularly to an electronic device for making a judgement according to the signal produced by the fan, and for controlling the playing of music.

2. Description of the Related Art

A computer mainly includes a central processing unit (CPU) acting as an operation center for the computer. Because the demands of the modern human beings on the processing speed of the computer are getting higher and higher, the operation frequency of the CPU has to be correspondingly increased in order to meet the demands of the modern human beings. Currently, the operation frequency of the CPU has reached above 2 GHz, which is quite quick. Thus, the future trend of the CPU inevitably has to enter an age of high-frequency and great heat. Consequently, a CPU with a high speed and strong functions has to be used in conjunction with a heat-dissipating device with high efficiency. The present heat-dissipating device mostly utilizes a heat slug and a fan to help the CPU to dissipate heat. Taking the fan as an example, the user typically couples the fan to the CPU so that the operating fan may dissipate heat of the operating CPU to the outside in order to keep the CPU in normal operations.

In general, the fan keeps outputting a fan rotating speed signal to a control unit to let it know the actual rotating speed of the fan. In addition, the control unit may adjust the rotating speed of the fan to decrease the temperature of the CPU according to the fan rotating speed signal and the temperature signal sensed by the temperature sensing unit around the CPU.

However, loud noises may be produced owing to the phenomena of rubbing and vibrating between the fan and the air or other mechanisms. With the increase of the power consumption of the current CPU, the heat generated by the CPU also increases. Correspondingly, the rotating speed of the fan has to be increased to help the CPU to dissipate the great heat. This, however, causes the problem of noises of the operating fan to be more and more serious, which is not the situation desired by the user.

### SUMMARY OF THE INVENTION

It is therefore an object of the invention to provide an electronic device. The designs of the electronic device of the invention for making a judgement and controlling playing of music according to the signal produced by the fan may greatly reduce the complaints of users with respect to noises produced by the operating fan, and thus achieve the object of converting noises of the fan into music.

The invention achieves the above-identified object by providing an electronic device connected to at least one fan, which produces noises and at least one signal during its operation. The electronic device includes a signal detection unit and a control processing unit. The signal detection unit detects the signal produced by the fan. The control processing unit makes a judgement according to the signal and controls playing of music accordingly.

The invention also achieves the above-identified object by providing an electronic apparatus including at least one fan, a signal detection unit and a control processing unit. The fan produces noises and at least one signal during it operation. The signal detection unit detects the signal produced by the fan, the control processing unit makes a judgement according to the signal and controls playing of music accordingly.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a block diagram showing an electronic device according to a first embodiment of the invention.

FIG. 2 is a block diagram showing an electronic apparatus according to a second embodiment of the invention.

FIG. 3 is a block diagram showing an electronic device according to a third embodiment of the invention.

### DETAILED DESCRIPTION OF THE INVENTION

1. First Embodiment

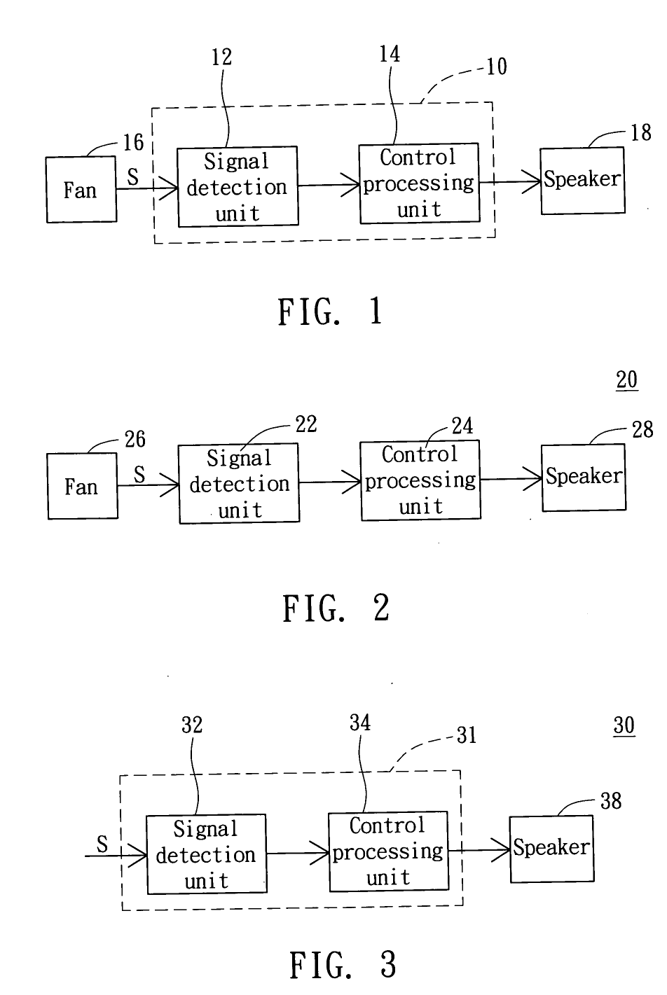

FIG. 1 is a block diagram showing an electronic device according to a first embodiment of the invention. As shown in FIG. 1, the electronic device 10 is connected to at least one fan 16, which produces noises and at least one signal S during its operation. The signal S may be a rotating speed, or a pulse or square wave signal of the fan 16. The electronic device 10 includes a signal detection unit 12 and a control processing unit 14. The signal detection unit 12 detects the signal S produced by the fan 16. The control processing unit 14 makes a judgement according to the signal S and controls playing of music accordingly. The electronic device 10 is further connected to a speaker 18 or other audio devices, which may be communicated with the control processing unit 14 to play the music. It is to be noted that the music may be stored in a memory or hard disk of the electronic device 10 or a memory unit of the control processing unit 14.

The method for playing the music of this embodiment will be described in the following. The control processing unit 14 stores at least one program, which defines at least one default interval having at least one limit value. If the signal S represents the rotating speed of the fan 16, the default interval may be, for example, 1000 to 2000 rpm, wherein the limit value is the maximum, such as 2000 rpm, of the default interval; or the limit value is the minimum, such as 1000 rpm, of the default interval. The control processing unit 14 compares the signal S with the limit value to judge whether or not the value of the signal S falls within the default interval. The program defines the playing speed or playing volume for the music corresponding to the default interval. The music at least includes an opus, and the program defines the opus corresponding to the default limit.

However, one of ordinary skill in the art may easily understand that the technology of the invention is not limited thereto. For example, the electronic device 10 may be a motherboard. The signal detection unit 12 may be a counter, a super input/output (super I/O) element or a clock counter. In addition, the control processing unit 14 may be a microprocessor, a central processing unit (CPU) or an ASIC (application specific integrated circuit). Furthermore, the fan 16, the speaker 18 or other audio devices also may be disposed in the electronic device 10.

2. Second embodiment

FIG. 2 is a block diagram showing an electronic apparatus according to a second embodiment of the invention. Referring to FIG. 2, the electronic apparatus 20 includes at least one fan 26, a signal detection unit 22, a control processing unit 24, a speaker 28 and a casing. The fan 26, the signal detection unit 22, the control processing unit 24 and the speaker 28 are all installed inside the casing. The operating fan 26 produces noises and at least one signal S, which may be a rotating speed, or a pulse or square wave signal of the fan 26. The signal detection unit 22 detects the signal S produced by the fan 26. The control processing unit 24 makes a judgement according to the signal S and controls playing of music accordingly. The speaker 28 or other audio devices may be communicated with the control processing unit 24 to play the music. It is to be noted that the music may be stored in a memory or hard disk of the electronic apparatus 20, and the music also may be stored in a memory unit of the control processing unit 24.

The method for playing the music of this embodiment will be described in the following. The control processing unit 24 stores at least one program, which defines at least one default interval having at least one limit value. The limit value may be a maximum or minimum of the default interval. The control processing unit 24 compares the signal S with the limit value to judge whether or not the value of the signal S falls within the default interval. The program defines the playing speed or playing volume for the music corresponding to the default interval. The music at least includes an opus, and the program defines the opus corresponding to the default limit.

However, one of ordinary skill in the art may easily understand that the technology of the invention is not limited thereto. For example, the electronic apparatus 20 may be a computer, a notebook computer or a server. The signal detection unit 22 may be a counter, a super input/output element or a clock counter. In addition, the control processing unit 24 may be a microprocessor, a central processing unit or an ASIC.

3. Third Embodiment

FIG. 3 is a block diagram showing an electronic device according to a third embodiment of the invention. In FIG. 3, the fan 30 produces noises and at least one signal S during its operation. The signal S may be a rotating speed, or a pulse or square wave signal of the fan 30. The fan 30 includes a circuit board 31, a signal detection unit 32 and a control processing unit 34. The signal detection unit 32 is disposed on the circuit board 31 to detect the signal S produced by the fan 30. The control processing unit 34 is disposed on the circuit board 31. The control processing unit 34 makes a judgement according to the signal S and controls playing of music accordingly. The fan 30 is further connected to a speaker 38 or other audio devices, which may be communicated with the control processing unit 34 to play the music. It is to be noted that the music may be stored in the memory of the fan 30 or the memory unit of the control processing unit 34.

The method for playing the music of this embodiment will be described in the following. The control processing unit 34 stores at least one program, which defines at least one default interval having at least one limit value. The limit value may be a maximum or minimum of the default interval. The control processing unit 34 compares the signal S with the limit value to judge whether or not the value of the signal S falls within the default interval. The program defines the playing speed or playing volume for the music corresponding to the default interval. The music at least includes an opus, and the program defines the opus corresponding to the default interval.

However, one of ordinary skill in the art may easily understand that the technology of the invention is not limited thereto. For example, the signal detection unit 32 may be a counter, a super input/output element or a clock counter. In addition, the control processing unit 34 may be a microprocessor, a central processing unit or an ASIC. Furthermore, the speaker 38 or other audio devices also may be disposed in the fan 30.

The designs of the invention for making the judgement and controlling the playing of music according to the signal produced by the fan may greatly reduce the complaints of users with respect to noises produced by the operating fan, and thus achieve the object of converting noises of the fan into music.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. An electronic device connected to at least one fan, which produces a plurality of noises and at least one signal during its operation, the electronic device comprising:
a signal detection unit for detecting the at least one signal produced by the at least one fan; and
a control processing unit for making a judgement according to the at least one signal and controlling playing of music accordingly.

2. The electronic device according to claim 1, wherein the signal detection unit comprises a counter.

3. The electronic device according to claim 1, wherein the at least one signal is a pulse or a square wave signal of the at least one fan.

4. The electronic device according to claim 1, wherein the control processing unit is a microprocessor or a central processing unit.

5. The electronic device according to claim 1, wherein the music comprises at least one opus.

6. The electronic device according to claim 1, wherein the control processing unit stores at least one program.

7. The electronic device according to claim 6, wherein the at least one program defines at least one default interval, which has at least one limit value.

8. The electronic device according to claim 7, wherein the control processing unit compares the at least one signal with the at least one limit value to judge whether or not a value of the at least one signal falls within the at least one default interval.

9. The electronic device according to claim 8, wherein the at least one program defines the music corresponding to the at least one default interval.

10. The electronic device according to claim 8, wherein the at least one program defines a playing speed or a playing volume for the music corresponding to the at least one default interval.

11. An electronic apparatus, comprising:
a casing;
at least one fan is installed inside the casing, which produces a plurality of noises and at least one signal during its operation;
a signal detection unit is installed inside the casing and is used for detecting the at least one signal produced by the at least one fan; and
a control processing unit is installed inside the casing and is used for making a judgement according to the at least one signal and controlling playing of music accordingly.

12. The electronic apparatus according to claim 11, wherein the signal detection unit comprises a counter.

13. The electronic apparatus according to claim 11, wherein the at least one signal is a pulse or a square wave signal of the at least one fan.

14. The electronic apparatus according to claim 11, wherein the control processing unit is a microprocessor or a central processing unit.

15. The electronic apparatus according to claim 11, wherein the music comprises at least one opus.

16. The electronic apparatus according to claim 11, wherein the control processing unit stores at least one program.

17. The electronic apparatus according to claim 16, wherein the at least one program defines at least one default interval, which has at least one limit value.

18. The electronic apparatus according to claim 17, wherein the control processing unit compares the at least one signal with the at least one limit value to judge whether or not a value of the at least one signal falls within the at least one default interval.

19. The electronic apparatus according to claim 18, wherein the at least one program defines the music corresponding to the at least one default interval.

20. The electronic apparatus according to claim 18, wherein the at least one program defines a playing speed or a playing volume for the music corresponding to the at least one default interval.
